(19) United States
(12) Patent Application Publication
(10) Pub. No.: US 2024/0421008 A1
(43) Pub. Date: Dec. 19, 2024

(54) SEMICONDUCTOR WAFER TEMPERATURE MEASUREMENT METHOD

(71) Applicant: Kioxia Corporation, Tokyo (JP)

(72) Inventors: Shunsuke OKADA, Suzuka (JP); Yoshifumi NISHIO, Kuwana (JP)

(73) Assignee: Kioxia Corporation, Tokyo (JP)

(21) Appl. No.: 18/738,117

(22) Filed: Jun. 10, 2024

(30) Foreign Application Priority Data
Jun. 16, 2023 (JP) 2023-099563

(51) Int. Cl. H01L 21/66; G01K 11/00; H01L 21/02; H01L 21/265

(52) U.S. Cl. CPC H01L 22/20; G01K 11/00; H01L 21/02667; H01L 21/26526

(57) ABSTRACT

A semiconductor wafer temperature measurement method according to the present embodiment includes introducing an impurity into a first surface of a wafer to form an amorphous layer on a side of the first surface of the wafer. The present temperature measurement method includes measuring a first film thickness that is the film thickness of the amorphous layer. The present temperature measurement method includes thermally treating the wafer to recrystallize part of the amorphous layer. The present temperature measurement method includes measuring a second film thickness that is the film thickness of the amorphous layer after the thermal treatment. The present temperature measurement method includes measuring the temperature of the wafer at the thermal treatment based on a film thickness difference between the first film thickness and the second film thickness.

### CROSS REFERENCE TO RELATED APPLICATIONS

This application is based upon and claims the benefit of priority from the prior Japanese Patent Application No. 2023-099563, filed on Jun. 16, 2023, the entire contents of which are incorporated herein by reference.

### FIELD

The embodiments of the present invention relate to a semiconductor wafer temperature measurement method.

### BACKGROUND

In an annealing process using a furnace such as a batch annealing furnace, difference in semiconductor wafer temperature among positions in the furnace is a factor that affects yield or characteristic degradation. Temperature in the furnace is controlled with a temperature profile in accordance with position in the furnace. However, difference in actual semiconductor wafer temperature occurs in some cases even with equivalent appearance on the temperature profile.

### BRIEF DESCRIPTION OF THE DRAWINGS

FIG. 1 is a flowchart illustrating an example of a semiconductor wafer temperature measurement method according to a first embodiment;

FIG. 2 is a cross sectional view illustrating the example of the semiconductor wafer temperature measurement method according to the first embodiment;

FIG. 3 is a graph illustrating an example of a temperature conversion chart according to the first embodiment;

FIG. 4 is a graph illustrating an example of a temperature measurement result according to the first embodiment; and

FIG. 5 is a graph illustrating an example of the crystal growth speed of an amorphous layer according to a second embodiment when recrystallizing.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor wafer temperature measurement method according to the present embodiment includes introducing an impurity into a first surface of a wafer to form an amorphous layer on a side of the first surface of the wafer. The present temperature measurement method includes measuring a first film thickness that is the film thickness of the amorphous layer. The present temperature measurement method includes thermally treating the wafer to recrystallize part of the amorphous layer. The present temperature measurement method includes measuring a second film thickness that is the film thickness of the amorphous layer after the thermal treatment. The present temperature measurement method includes measuring the temperature of the wafer at the thermal treatment based on a film thickness difference between the first film thickness and the second film thickness.

### First Embodiment

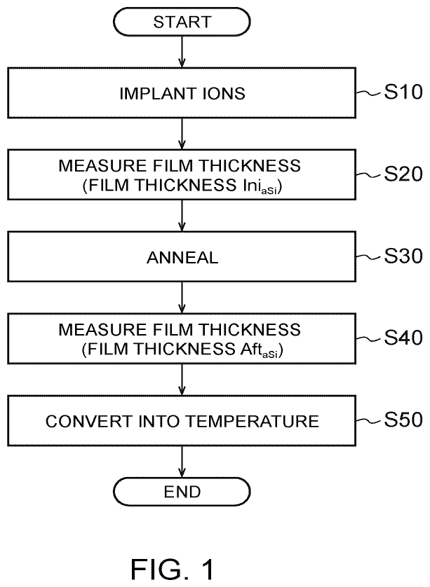

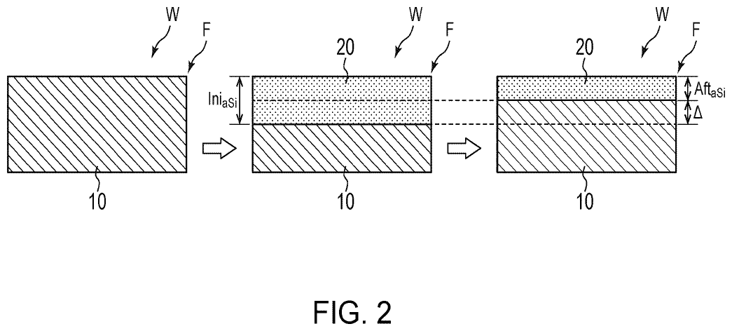

FIG. 1 is a flowchart illustrating an example of a temperature measurement method for a semiconductor wafer W according to a first embodiment. FIG. 2 is a cross sectional view illustrating the example of the temperature measurement method for the semiconductor wafer W according to the first embodiment. The actual temperature of the semiconductor wafer W at annealing in a furnace such as a batch annealing furnace is measured in accordance with FIGS. 1 and 2.

First, ion implantation is performed on the semiconductor wafer W (S10). More specifically, an impurity is introduced (implanted) into a surface F of the semiconductor wafer W to form an amorphous layer 20 on a side of the surface F of the semiconductor wafer W.

The semiconductor wafer W includes a semiconductor substrate 10. The semiconductor substrate 10 is, for example, a single-crystal silicon (Si) substrate. The amorphous layer 20 is formed at part of the semiconductor substrate 10 by implantation damage. As illustrated in FIG. 2, an amorphous Si layer (the amorphous layer 20) containing P and having a film thickness Ini_{aSi} is formed on the surface F (upper surface) side of the semiconductor wafer W. The film thickness Ini_{aSi} is the film thickness of the amorphous layer 20 after the ion implantation and before annealing.

The dopant (impurity) of the ion implantation is, for example, P⁺. However, the dopant is not limited to P⁺. Energy of the ion implantation is, for example, 20 keV. The ion implantation is performed under an implantation condition that, for example, the film thickness of the amorphous layer 20 is equal to or larger than 6 nm. The dose amount of the ion implantation is, for example, 1×10¹⁵ ions/cm². The concentration of the impurity in the amorphous layer 20 is, for example, equal to or larger than 1×10¹⁹ atoms/cm³.

Subsequently, the film thickness Ini_{aSi} of the amorphous layer 20 is measured (S20). The film thickness measurement is performed by, for example, spectroscopic ellipsometry. However, the film thickness measurement is not limited thereto and may be performed by transmission electron microscope (TEM) observation, scanning electron microscope (SEM) observation, or the like.

Subsequently, the semiconductor wafer W is annealed in a furnace (S30). More specifically, the semiconductor wafer W is thermally treated to recrystallize part of the amorphous layer 20.

The amorphous layer 20 contacting the single-crystal semiconductor substrate 10 is recrystallized through the annealing. As illustrated in FIG. 2, the film thickness of the amorphous layer 20 changes to a film thickness Aft_{aSi}. The film thickness Aft_{aSi} is the film thickness of the amorphous layer 20 after the annealing. The change amount of the film thickness of the amorphous layer 20 depends on crystal growth (solid-phase epitaxial growth) speed in a case where a treatment time is fixed.

The annealing is performed at an optional treatment temperature for an optional treatment time in an inert atmosphere. The annealing is performed under, for example, a condition at 400° C. for 240 minutes in an N₂ atmosphere.

Subsequently, the film thickness Aft_{aSi} of the amorphous layer 20 is measured (S40). The film thickness measurement at step S40 is performed by the same method as that at step S20. A film thickness difference Δ (Ini_{aSi}−Aft_{aSi}) is calculated from the film thickness Ini_{aSi} and the film thickness Aft_{aSi} thus measured.

Subsequently, the film thickness difference Δ is converted into temperature (S50). Specifically, the temperature of the semiconductor wafer W at the thermal treatment is measured based on the film thickness difference Δ. More specifically, the film thickness difference Δ is converted into the temperature of the semiconductor wafer W at the thermal treatment based on a preset relation between the film thickness difference Δ and the temperature of the semiconductor wafer W at the thermal treatment.

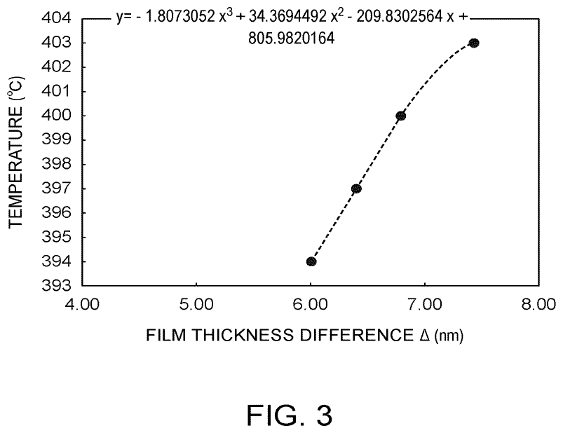

FIG. 3 is a graph illustrating an example of a temperature conversion chart according to the first embodiment. The vertical axis of the graph represents temperature (set temperature of the furnace). The horizontal axis of the graph represents the film thickness difference Δ.

Four data points illustrated in FIG. 3 represent results of measurement of the relation (temperature sensitivity of the change amount of the film thickness) between the film thickness difference Δ and temperature, which is executed in advance. In a case where the annealing is performed with the set temperature of the furnace at 400° C., a plurality of set temperatures are selected from a temperature range including 400° C. at measurement of the relation between temperature and the film thickness difference Δ. In the example illustrated in FIG. 3, the four temperatures of 394° C., 397° C., 400° C., and 403° C. are selected as set temperatures.

The dotted line illustrated in FIG. 3 represents a result of fitting with the four data points. A polynomial is obtained by the fitting. The film thickness difference Δ can be converted into temperature by substituting the film thickness difference Δ calculated at step S40 into the polynomial obtained by the fitting.

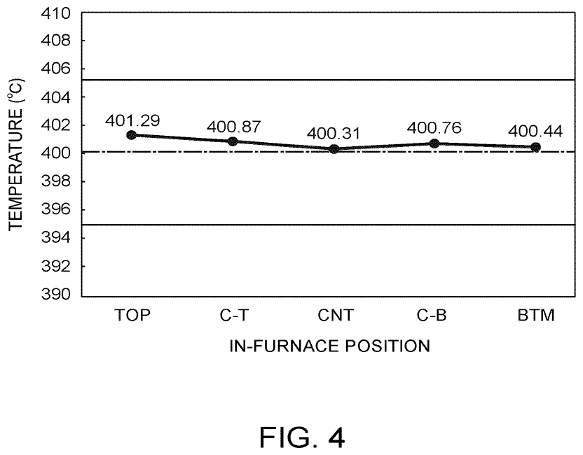

FIG. 4 is a graph illustrating an example of a temperature measurement result according to the first embodiment. The vertical axis of the graph represents temperature (actual temperature or temperature converted at step S50). The horizontal axis of the graph represents position in the furnace. The example illustrated in FIG. 4 indicates five in-furnace positions (TOP, C-T, CNT, C-B, and BTM) from a top to a bottom of a batch annealing furnace in which a plurality of semiconductor wafers W are thermally treated.

As illustrated in FIG. 4, the temperature of the semiconductor wafer W is measured at the five in-furnace positions. Accordingly, temperature distribution in the batch annealing furnace for the set temperature of 400° C. can be obtained.

As described above, according to the first embodiment, the temperature of the semiconductor wafer W at the thermal treatment is measured based on the film thickness difference Δ. Accordingly, the temperature of the semiconductor wafer W can be more highly accurately and more easily measured.

Since the film thickness difference Δ through annealing for the same semiconductor wafer W is used, it is possible to reduce influence of inter-sample variance of the semiconductor wafer W in a case of in-furnace position evaluation or the like. Accordingly, the temperature of the semiconductor wafer W can be more highly accurately measured.

In the first embodiment, a cover film that covers the surface F is not formed before the impurity is introduced. The cover film is, for example, a protective film. The cover film includes, for example, an oxide film. The cover film further includes, for example, a conductive metal film in some cases.

The annealing temperature (treatment temperature) is not limited to 400° C. but may be equal to or higher than 100° C. and equal to or lower than 700° C.

A thermocouple-equipped temperature measurement monitor wafer is used in some cases in a method of more highly accurately measuring temperature in the furnace. However, the temperature measurement monitor wafer is expensive and sometimes difficult to use in condition setting usage.

However, according to the first embodiment, it is possible to more easily measure temperature in the furnace without using the temperature measurement monitor wafer.

### Second Embodiment

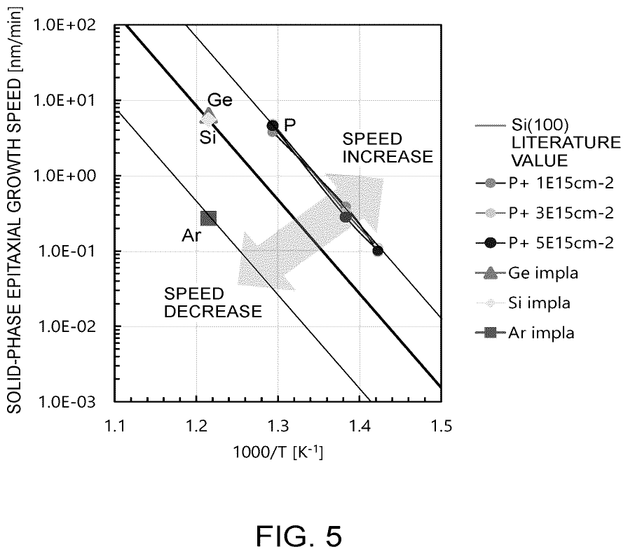

FIG. 5 is a graph illustrating an example of the crystal growth speed of the amorphous layer 20 according to a second embodiment when recrystallizing. The second embodiment is different from the first embodiment in that the element (element type) and concentration of the dopant are changed in accordance with annealing conditions.

The vertical axis of the graph represents the crystal growth speed (solid-phase epitaxial growth speed). The horizontal axis of the graph represents 1000/T where T is the annealing temperature. In the example illustrated in FIG. 5, P⁺, Ge, Si, and Ar are indicated as the dopant. The dose amount of P⁺ is 1×10¹⁵ ions/cm², 3×10¹⁵ ions/cm², and 5×10¹⁵ ions/cm². The straight line overlapping data points of Si and Ge represents a literature value of Si(100).

In the second embodiment, at step S10, the impurity is introduced into the surface F of the semiconductor wafer W so that the crystal growth speed of the amorphous layer 20 when recrystallizing is desired speed. More specifically, the impurity is introduced into the surface F of the semiconductor wafer W with an element or concentration of the impurity in accordance with temperature at the thermal treatment. The annealing treatment time is fixed.

As illustrated in FIG. 5, a linear relation exists between 1000/T and the crystal growth speed (logarithmic scale). Accordingly, the crystal growth speed increases as the annealing temperature T increases. Moreover, the crystal growth speed decreases as the annealing temperature T decreases.

The following first describes the relation between the crystal growth speed and the element of the dopant.

The straight line representing the relation between the annealing temperature T and the crystal growth speed translates with change of the element of the dopant. With Ar, the crystal growth speed decreases as compared to the literature value of Si(100). With P, the crystal growth speed increases as compared to the literature value of Si(100).

In a case where the crystal growth speed is fast, crystal growth potentially reaches the outermost surface of the semiconductor wafer W during annealing. In this case, the film thickness difference Δ cannot be used for temperature conversion. In a case where the crystal growth speed is slow, the film thickness difference Δ that is sufficient for temperature measurement is potentially difficult to obtain, depending on the accuracy of film thickness measurement.

Thus, the element of the dopant is changed so that the crystal growth speed is in a desired speed range. Accordingly, the temperature of the semiconductor wafer W can be more appropriately measured in accordance with a temperature zone in which temperature evaluation is performed. For example, since the crystal growth speed increases as the annealing temperature T increases, a dopant that decreases the crystal growth speed is selected. The dopant that decreases the crystal growth speed is, for example, Ar. Moreover, since the crystal growth speed decreases as the annealing temperature T decreases, a dopant that increase the crystal growth speed is selected. The dopant that increases the crystal growth speed is, for example, P.

The element of the dopant may be selected from among, for example, at least one or more of silicon (Si), germanium (Ge), phosphorus (P), arsenic (As), argon (Ar), or antimony (Sb).

The relation between the crystal growth speed and the concentration of the dopant will be described below.

The straight line representing the relation between the annealing temperature T and the crystal growth speed translates with change of the concentration (dose amount) of the dopant as well. Change of the crystal growth speed due to change of the concentration of the dopant is smaller than change of the crystal growth speed due to change of the element of the dopant. In the example illustrated in FIG. 5, the crystal growth speed increases as the dose amount (concentration) of P⁺ increases. Moreover, the crystal growth speed decreases as the dose amount (concentration) of P⁺ decreases.

The concentration of the dopant may be changed so that the crystal growth speed is in a desired speed range.

The semiconductor wafer W is thermally treated for a predetermined time or longer. For example, thermal treatment for a relatively long time of several ten minutes to several hours is performed in a batch annealing furnace. In a case where an element type such as Ar or P is used, temperature measurement of the semiconductor wafer W is possible even with thermal treatment for a relatively long time.

As in the second embodiment, the element (element type) and concentration of the dopant may be changed in accordance with annealing conditions. A temperature measurement method for the semiconductor wafer W according to the second embodiment can obtain the same effects as those of the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor wafer temperature measurement method comprising:
introducing an impurity into a first surface of a wafer to form an amorphous layer on a side of the first surface of the wafer;
measuring a first film thickness that is the film thickness of the amorphous layer;
thermally treating the wafer to recrystallize part of the amorphous layer;
measuring a second film thickness that is the film thickness of the amorphous layer after the thermal treatment; and
measuring the temperature of the wafer at the thermal treatment based on a film thickness difference between the first film thickness and the second film thickness.

2. The semiconductor wafer temperature measurement method according to claim 1, further comprising introducing the impurity into the first surface of the wafer so that crystal growth speed of the amorphous layer when recrystallizing is desired speed.

3. The semiconductor wafer temperature measurement method according to claim 2, further comprising introducing the impurity into the first surface of the wafer with an element or concentration of the impurity in accordance with temperature at the thermal treatment.

4. The semiconductor wafer temperature measurement method according to claim 1, wherein the element of the impurity includes at least one of Si, Ge, P, As, Ar, or Sb.

5. The semiconductor wafer temperature measurement method according to claim 1, further comprising introducing the impurity into the wafer without forming a cover film that covers the first surface.

6. The semiconductor wafer temperature measurement method according to claim 1, further comprising thermally treating the wafer for a predetermined time or longer.

7. The semiconductor wafer temperature measurement method according to claim 1, wherein the measuring of the temperature of the wafer at the thermal treatment based on the film thickness difference includes converting the film thickness difference into the temperature of the wafer at the thermal treatment based on a preset relation between the film thickness difference and the temperature of the wafer at the thermal treatment.

8. The semiconductor wafer temperature measurement method according to claim 2, wherein the element of the impurity includes at least one of Si, Ge, P, As, Ar, or Sb.

9. The semiconductor wafer temperature measurement method according to claim 3, wherein the element of the impurity includes at least one of Si, Ge, P, As, Ar, or Sb.
